(19) United States
(12) Patent Application Publication
(10) Pub. No.: US 2014/0061697 A1
(43) Pub. Date: Mar. 6, 2014

(54) LIGHT EMITTING DIODE PACKAGE AND METHOD FOR MANUFACTURING THE SAME

(71) Applicant: Advanced Optoelectronic Technology, Inc., Hsinchu Hsien (TW)

(72) Inventors: HOU-TE LIN, Hukou (TW); CHAO-HSIUNG CHANG, Hukou (TW); PIN-CHUAN CHEN, Hukou (TW); LUNG-HSIN CHEN, Hukou (TW); WEN-LIANG TSENG, Hukou (TW)

(21) Appl. No.: 13/912,211

(22) Filed: Jun. 7, 2013

(30) Foreign Application Priority Data
Aug. 30, 2012 (CN) 2012103147901

(51) Int. Cl. H01L 33/60; H01L 33/62

(52) U.S. Cl. CPC H01L 33/60; H01L 33/62
USPC 257/98; 438/27

(57) ABSTRACT

An LED package includes adjacent first and second electrodes, first and second extension electrodes protruding sideward from the first and second electrodes, a molded body surrounding the first and second electrodes and an LED die. The molded body forms a reflecting cup located over the first and second electrodes, with each reflecting cup defining a receiving cavity in a top face thereof to receive the LED die. The first and second extension electrodes are exposed from an outer periphery of the molded body. The first electrode has a first bottom face. The second electrode has a second bottom face. The first and second bottom faces of the first and second electrodes are exposed out from a bottom face of the molded body. A method for manufacturing the LED package is also provided.

### BACKGROUND

1. Technical Field

The present disclosure relates generally to semiconductor packages, and more particular to a light emitting diode (LED) package and a method for manufacturing the same.

2. Description of Related Art

LEDs are solid state light emitting devices formed of semiconductors, which are more stable and reliable than other conventional light sources such as incandescent bulbs. Thus, LEDs are being widely used in various fields such as numeral/character displaying elements, signal lights, light sources for lighting and display devices.

In a typical LED package, an LED die is mounted on a substrate and electrically connected to electrodes formed on the substrate via gold wires. In use, a majority of heat generated by the LED die is conducted from the LED die to the electrodes via the gold wires, and then the heat absorbed by the electrodes is transferred to the substrate through which the heat is finally dissipated into ambient environment. However, heat-dissipating efficiency of the LED package is relatively low due to the long heat transfer paths formed between the LED die and the ambient environment.

What is needed therefore is a light emitting diode package and a method for manufacturing the same which can overcome the above mentioned limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the views.

FIG. 1 is a schematic, cross section view of a light emitting diode package in accordance with an embodiment of the present disclosure.

FIG. 2 is a top plan view of the light emitting diode package of FIG. 1.

FIG. 3 is a bottom plan view of the light emitting diode package of FIG. 1.

FIG. 4 is a side view of the light emitting diode package of FIG. 1.

FIGS. 5A and 5B are a flow chart of a method for manufacturing the light emitting diode package in accordance with an embodiment of the present disclosure.

FIGS. 6, 8 and 10 are top plan views of the light emitting diode package obtained by different steps of the method shown in FIGS. 5A and 5B.

FIG. 7 is a cross section view taken along line VII-VII of FIG. 6.

FIG. 9 is a cross section view taken along line IX-IX of FIG. 8.

FIG. 11 is a side-view type light source incorporating the light emitting diode package of FIG. 2.

### DETAILED DESCRIPTION

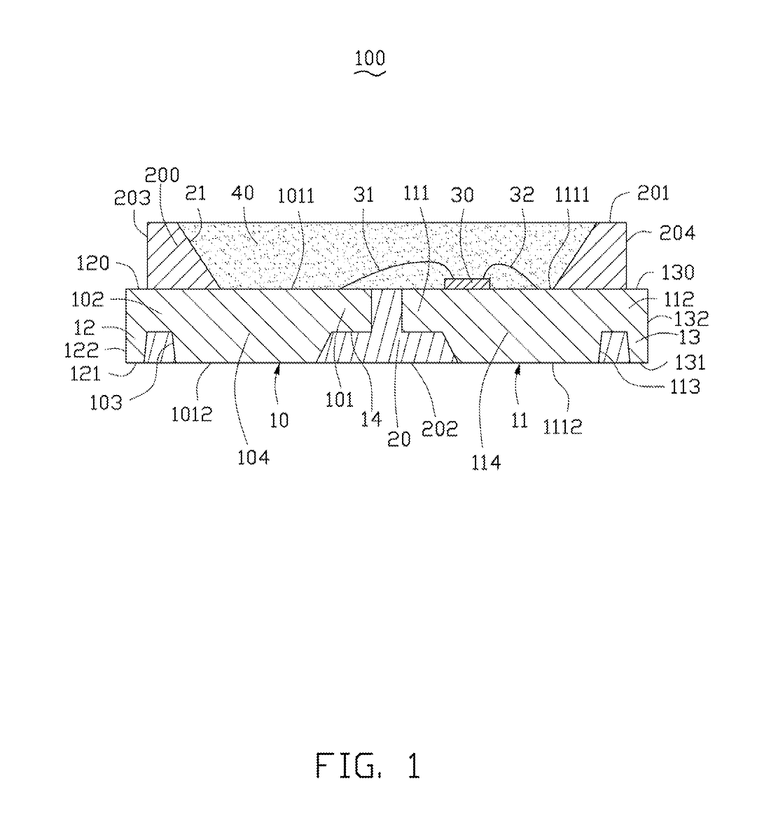

Referring to FIG. 1, a light emitting diode (LED) package 100 in accordance with an exemplary embodiment of the present disclosure includes a first electrode 10, a second electrode 11 adjacent to the first electrode 11, a molded body 20 having a reflecting cup 200 surrounding the first and second electrodes 10, 11, and an LED die 30 mounted on the second electrode 11. The LED package 100 further includes a first extension electrode 12 protruding sideward from the first electrode 10, and a second extension electrode 13 protruding sideward from the second electrode 11. The first and second extension electrodes 12, 13 are exposed from lateral sides 203, 204 of the reflecting cup 200 of the molded body 20, respectively.

The first electrode 10 has a first top face 1011, and a first bottom face 1012 opposite to and parallel to the first top face 1011. The second electrode 11 has a second top face 1111, and a second bottom face 1112 opposite to and parallel to the second top face 1111. The first top face 1011 of the first electrode 10 is coplanar with the second top face 1111 of the second electrode 11. The first bottom face 1012 of the first electrode 10 is coplanar with the second bottom face 1112 of the second electrode 11. The first bottom face 1012 and the second bottom face 1112 of the first and second electrodes 10, 11 are exposed out from a bottom face 202 of the molded body 20.

Each of the first and second electrodes 10, 11 has a T-shaped transverse cross-section along a thickness direction thereof. The first electrode 10 has a first central portion 104 and a first side portion 101, and the first side portion 101 protrudes sideward from the first central portion 104 towards the second electrode 11. The first central portion 104 has a thickness larger than that of the first side portion 101. The second electrode 11 has a second central portion 114 and a second side portion 111, and the second side portion 111 protrudes sideward from the second central portion 114 towards the first electrode 10. The second central portion 114 has a thickness larger than that of the second side portion 111. The first side portion 101 faces toward the second portion 111.

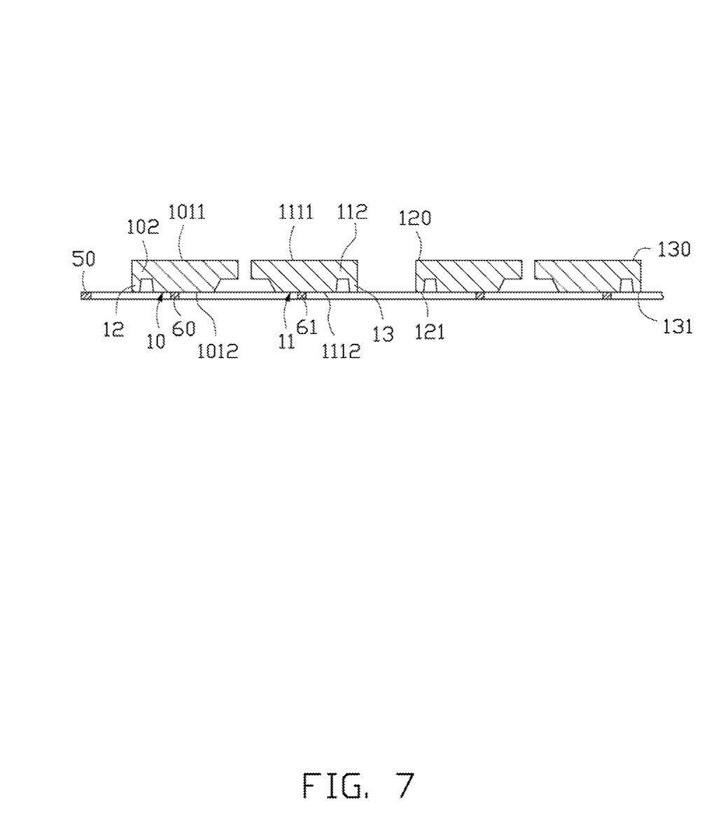

Referring to FIG. 7 also, the first and second electrodes 10, 11 cooperatively define an elongate groove 14 therebetween. The groove 14 includes an upper portion 141 and a lower portion 142 communicated with the upper portion 141. The upper portion 141 is located between the first side portion 101 of the first electrode 10 and the second side portion 111 of the second electrode 11. The lower portion 142 is located between the first central portion 104 of the first electrode 10 and the second central portion 114 of the second electrode 11. The upper portion 141 has a width less than that of the lower portion 142. In the present disclosure, the molded body 20 fills in the groove 14.

In the present disclosure, a width of the lower portion 142 of the groove 14 increases gradually along a top-to-bottom direction of the first and second electrodes 10, 11. The first and second electrodes 10, 11 are embedded in the molded body 20.

The reflecting cup 200 of the molded body 20 has a top face 201, and the bottom face 202 opposite to and parallel to the top face 201. The bottom face 202 is coplanar with the first bottom face 1012 and the second bottom face 1112. The reflecting cup 200 defines a receiving cavity 21 for receiving the LED die 30 therein, and the receiving cavity 21 is defined in the top face 201 of the reflecting cup 200. The receiving cavity 21 extends downwardly from the top face 111 of the reflecting cup 200 to the first and second electrodes 10, 11. The first and second top faces 1011, 1111 are partially exposed at the bottom of the receiving cavity 21. The receiving cavity 21 of the reflecting cup 200 is communicated with the groove 14.

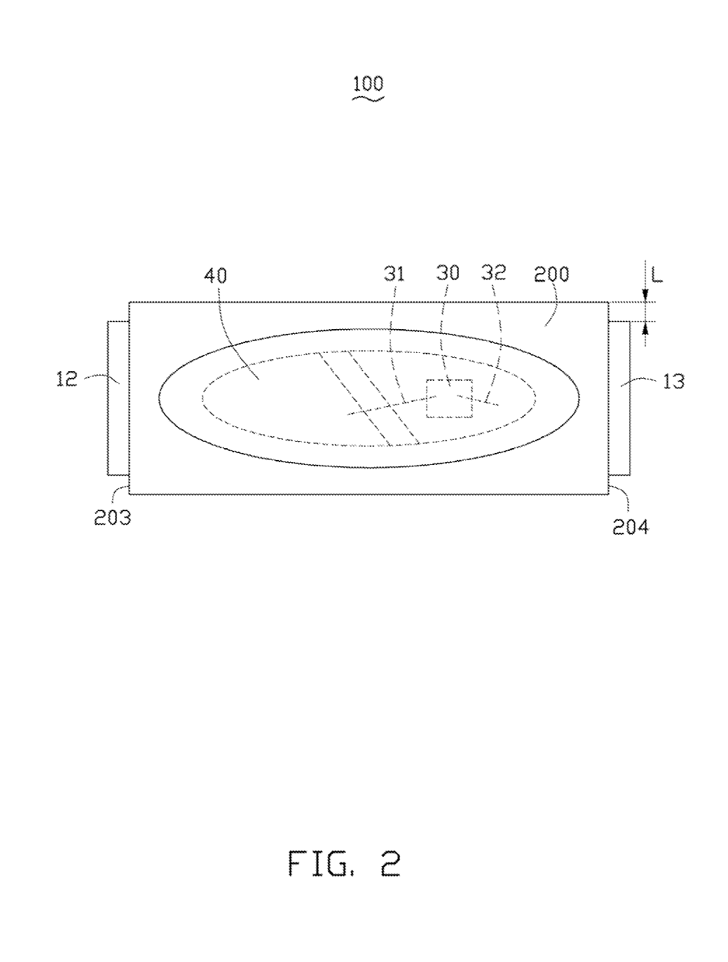

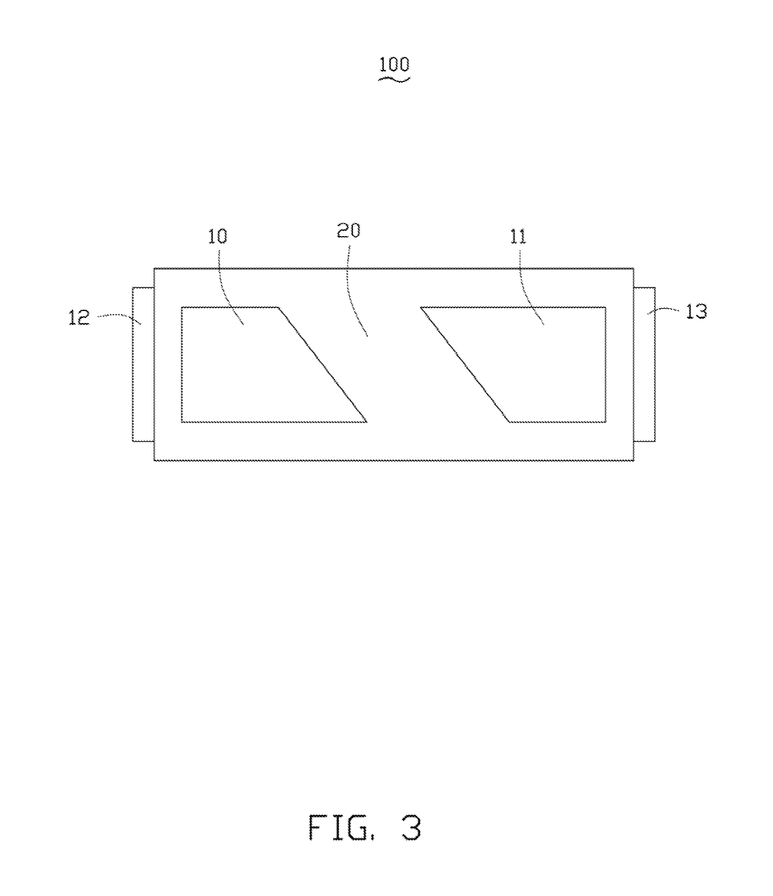

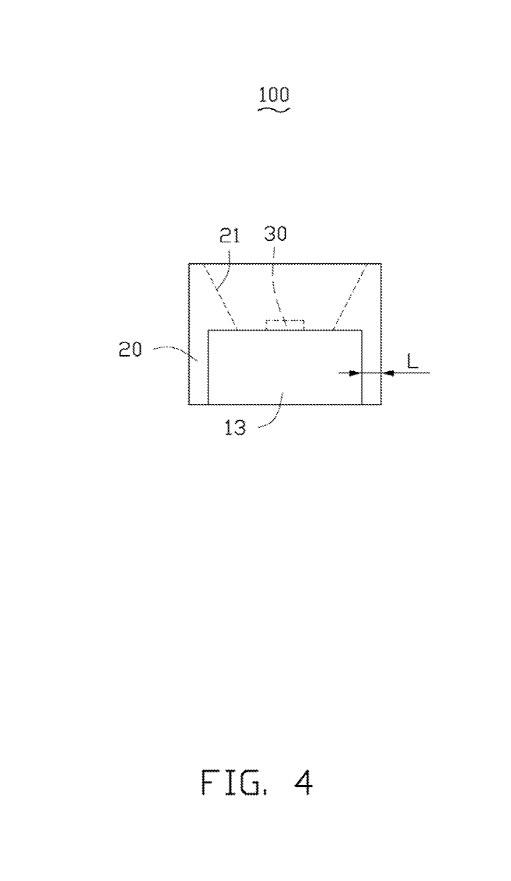

Referring to FIGS. 2, 3 and 4 also, the LED die 30 is received in the receiving cavity 21 and electrically connected to the first, second electrodes 10, 11, respectively. An encapsulant layer 40 is formed in the receiving cavity 21 to encapsulate the LED die 30 therein. The encapsulant layer 40 contains phosphor (not shown) scattered therein to convert wavelength of the light emitted from the LED die 30. In the present disclosure, the LED die 30 is electrically connected to the first and second electrodes 10, 11 via gold wires 31, 32. In another embodiment, the LED die 30 could be adhered and electrically connected to the first and second electrodes 10, 11 by a flip-chip technology.

The first extension electrode 12 is extended outwardly and downwardly from an outer end 102 of the first electrode 10. The second extension electrode 11 is extended outwardly and downwardly from an outer end 112 of the second electrode 11. The outer end 112 is far away from the first electrode 10. The outer end 102 is far away from the second electrode 11. The reflecting cup 200 has a width larger than that of the first and second extension electrodes 12, 13 in a width direction of the LED package 100. In the present disclosure, as shown in FIG. 2, a distance L between an edge of the second extension electrode 13 and an edge of the molded body 20 is less than 100 micrometers.

The first extension electrode 12 has a top face 120, a bottom face 121 opposite to and parallel to the top face 120, and a lateral face 122 connecting the top face 120 and the bottom face 121. The top face 120 of the first extension electrode 12 is coplanar with the first top face 1011 of the first electrode 10. The second extension electrode 13 has a top face 130, a bottom face 131 opposite to and parallel to the top face 130, and a lateral face 132 connecting the top face 130 and the bottom face 131. The top face 130 of the second extension electrode 13 is coplanar with the second top face 1111 of the second electrode 11. The bottom face 121 of the first extension electrode 12 is coplanar with the first bottom face 1012 of the first electrode 10. The bottom face 131 of the second extension electrode 13 is coplanar with the second bottom face 1112 of the second electrode 11.

The first electrode 10 and the first extension electrode 12 cooperatively define a first slot 103 therebetween. The second electrode 11 and the second extension electrode 13 cooperatively define a second slot 113 therebetween. The molded body 20 fills in the first and second slots 103, 113.

The top faces 120, 130, the bottom faces 121, 131, and the lateral faces 122, 132 of the first and second extension electrodes 12, 13 are totally exposed out of the molded body 20.

In use, heat generated from the LED die 30 is conducted to the first and second electrodes 10, 11 via wires 31, 32. The LED package 100 is electrically connected to a remote power source (not shown) via the first and second extension electrodes 12, 13. Part of the heat absorbed by the first electrode 10 is dissipated to the ambient environment through the bottom face 1012 of the first electrode 10. Part of the heat absorbed by the second electrode 11 is dissipated to the ambient environment through the bottom face 1112 of the second electrode 11. Part of the heat absorbed by the first and second electrodes 10, 11 is dissipated to the ambient environment through the first and second extension electrodes 12, 13. Thus, the LED package 100 can have a high heat-dissipating efficiency.

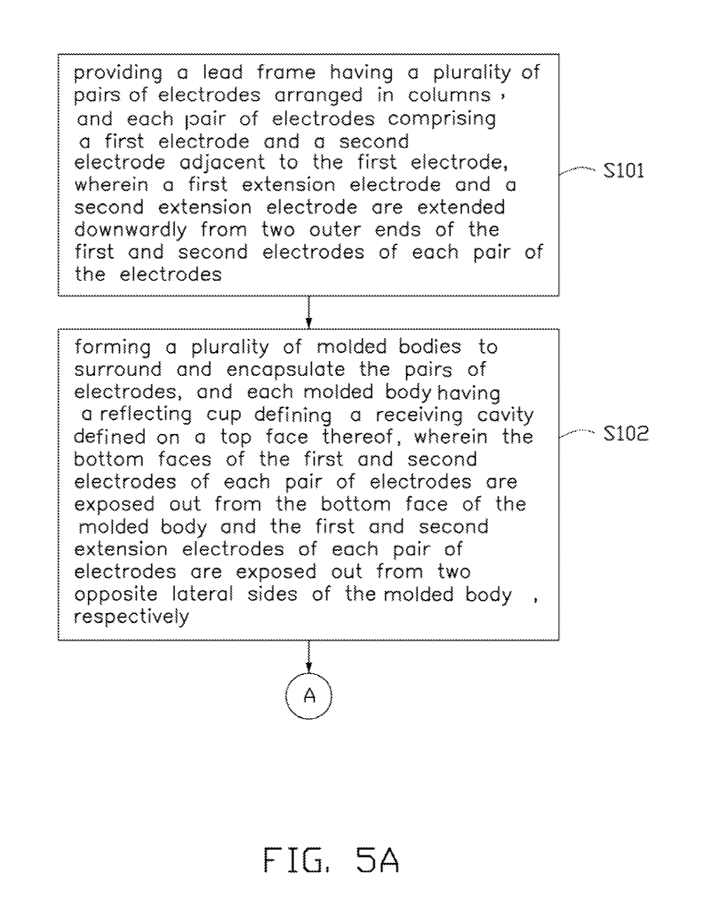

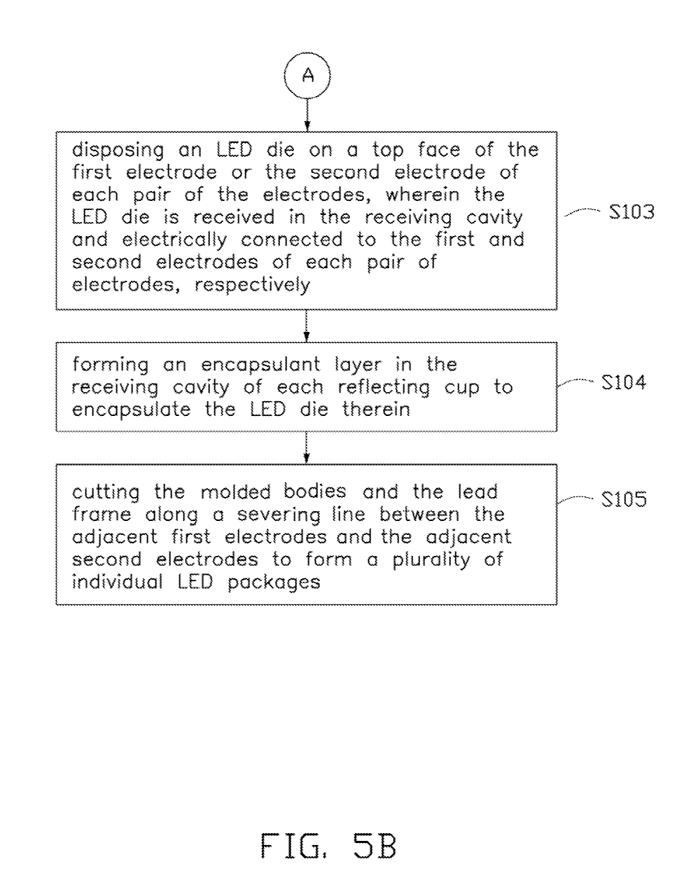

Referring to FIGS. 5A and 5B , a method for manufacturing the LED package 100 in accordance with an exemplary embodiment of the present disclosure is shown.

The method includes the following steps:

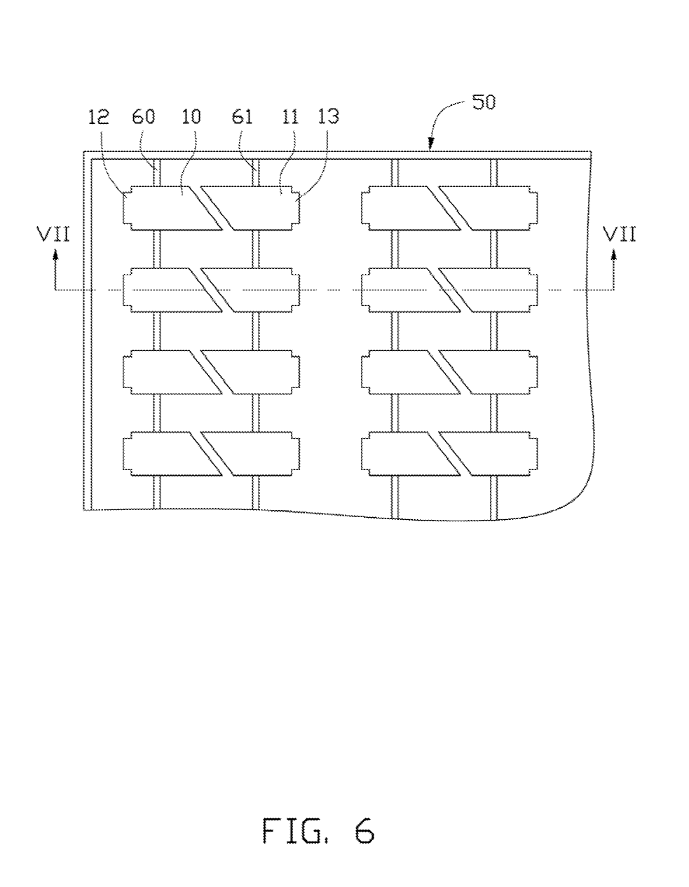

Step A (also referring to FIGS. 6-7), a lead frame 50 is provided, and the lead frame 50 includes a plurality of pairs of electrodes arranged in a matrix. Each pair of electrodes includes a first electrode 10 and a second electrode 11 adjacent to the first electrode 10. The first and second electrodes 10, 11 are used for connecting with different polarities of a power source. The adjacent first electrodes 10 arranged in a column are linearly connected together by a first connecting bar 60, and the adjacent second electrodes 11 arranged in a column are linearly connected together by a second connecting bar 61. There are two columns of first electrodes 10 and two columns of second electrodes 11. A first extension electrode 12 protrudes sideward from the first electrode 10, and a second extension electrode 13 protrudes sideward from the second electrode 11.

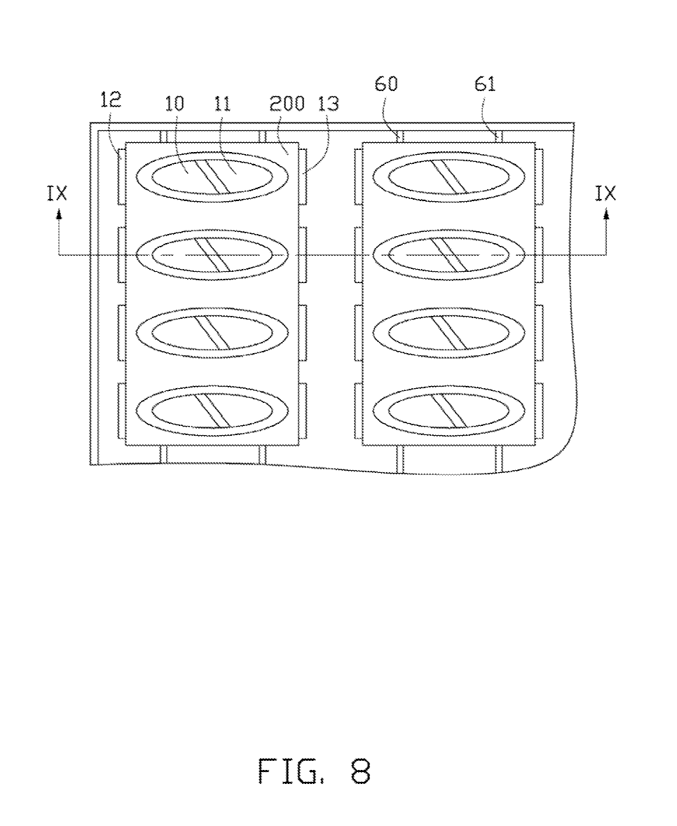

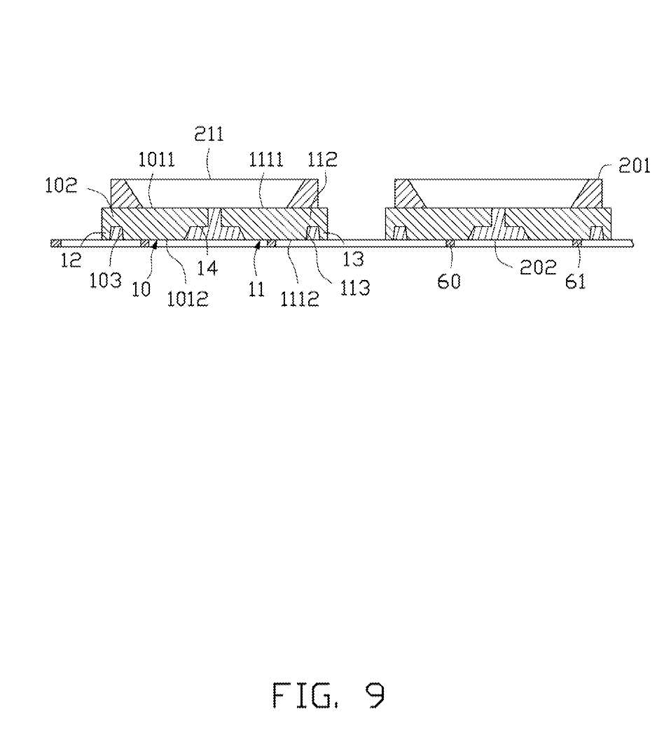

Step B (also referring to FIGS. 8-9), a plurality of molded bodies 20 (i.e., two molded bodies 20 in FIG. 8) are formed to correspond to the plurality of pairs of the first and second electrodes 10, 11, each molded body 20 surrounding and covering therein the first and second electrodes 10, 11 disposed in two adjacent columns. Each molded body 20 includes a plurality reflecting cups 200, each reflecting cup 200 located over a corresponding pair of first and second electrodes 10, 11. Each reflecting cup 200 defines a receiving cavity 21 for receiving the LED die 30 therein, and the receiving cavity 21 is defined in a top face 201 of the reflecting cup 200. A first and second extension electrodes 12, 13 are exposed from opposite lateral sides 203, 204 of the molded body 20, respectively. The top faces 120, 130, the bottom faces 121, 131, and the lateral faces 122, 132 of the first and second extension electrodes 12, 13 are totally exposed out of the molded body 20.

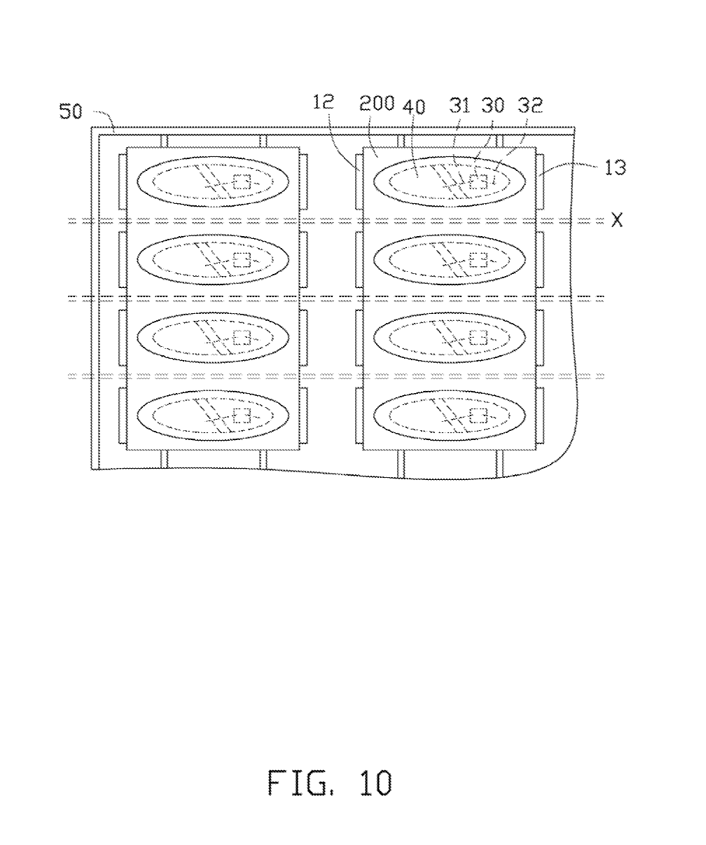

Step C (also referring to FIG. 10), a plurality of LED dies 30 are received in the receiving cavities 21. Each LED die 30 is electrically connected to the first and second electrodes 10, 11 being exposed at a bottom of the corresponding receiving cavity 21.

Step D (also referring to FIG. 10), an encapsulant layer 40 is formed in each receiving cavity 21 to encapsulate the LED die 30 therein. The encapsulant layer 40 contains phosphor (not shown) scattered therein to convert wavelength of the light emitted from the LED die 30.

Step E (also referring to FIGS. 1 and 10), the molded bodies 20 and the lead frame 50 are cut along severing lines X to obtain a plurality of individual LED packages 100 along a top-to-bottom direction of reflecting cups 200 as shown in FIG. 10, and the severing lines X are located between two adjacent first electrodes 10 and two adjacent second electrodes 11. In the present disclosure, the severing lines X are perpendicular to the first and second connecting bars 60, 61.

In addition to being used as a top-view type light source shown in FIG. 1, the

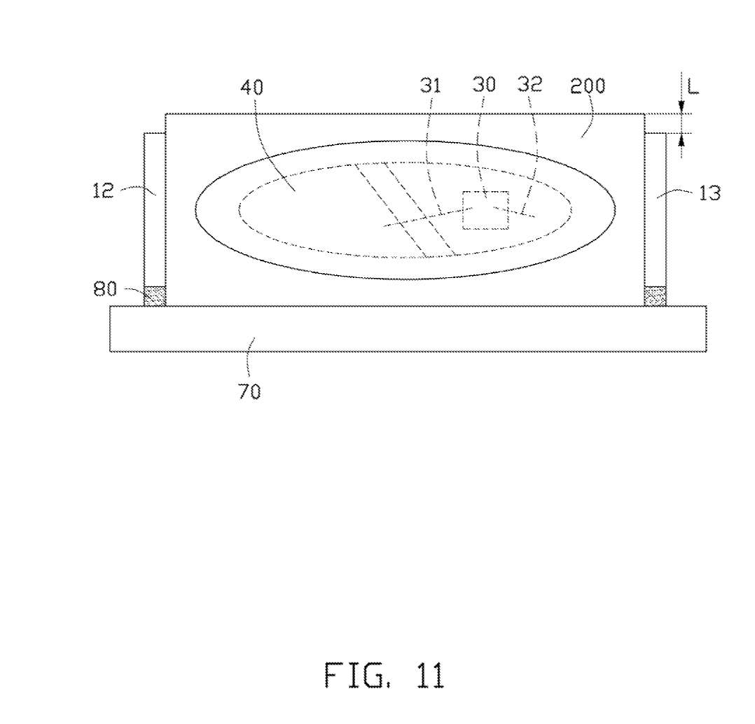

LED package 100 could be used as a side-view type light source as shown in FIG. 11. As shown in FIG. 11, the LED package 100 is connected to an external printed circuit board (PCB) 70. And a solder material 80 is filled in the gaps (not labeled) between the first, second extension electrodes 12, 13 and the PCB 70, thereby making an electrical connection between the LED package 100 and the PCB 70. In the present disclosure, the bottom faces 1012, 1112 of the first and second electrode 10, 11 are exposed out from the bottom face 202 of the molded body 20, through which heat generated by the LED die 30 is effectively dissipated to the ambient environment.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A light emitting diode (LED) package comprising:
a first electrode and a second electrode adjacent to the first electrode, wherein the first electrode comprises a first top face and a first bottom face far away from the first top face, and the second electrode comprises a second top face and a second bottom face far away from the second top face;
a first extension electrode protruding sideward from the first electrode in a direction away from the second electrode, and a second extension electrode protruding sideward from the second electrode in a direction away from the first electrode;
a molded body surrounding and covering the first and second electrodes, the molded body comprising a reflecting cup located over the first and second electrodes, and the reflecting cup defining a receiving cavity in a top face thereof; and
an LED die received in the receiving cavity, wherein the LED die is electrically connected to portions of the first and second electrodes exposed in the receiving cavity;
wherein the first and second extension electrodes are exposed from an outer periphery of the molded body; and
wherein the first and second bottom faces of the first and second electrodes are exposed out from a bottom face of the molded body.

2. The LED package of claim 1, wherein the first and second electrodes are embedded in the molded body, and top faces of the first and second electrodes are partially exposed at bottom of the receiving cavity.

3. The LED package of claim 1, wherein the reflecting cup has a width larger than that of the first and second extension electrodes in a width direction of the LED package.

4. The LED package of claim 3, wherein a distance between an edge of the second extension electrode and a corresponding edge of the molded body is less than 100 micrometers.

5. The LED package of claim 1, wherein the first extension electrode is extended outwardly and downwardly from an outer end of the first electrode, and the second extension electrode is extended outwardly and downwardly from an outer end of the second electrode.

6. The LED package of claim 5, wherein the outer end of the first electrode is far away from the second electrode, and the outer end of the second electrode is far away from the first electrode.

7. The LED package of claim 1, wherein the first extension electrode has a top face, a bottom face opposite to and parallel to the top face, and a lateral face connecting the top face and the bottom face, and the second extension electrode has a top face, a bottom face opposite to and parallel to the top face, and a lateral face connecting the top face and the bottom face.

8. The LED package of claim 7, wherein the top face of the first extension electrode is coplanar with the top face of the second extension electrode, and the bottom face of the first extension electrode is coplanar with the bottom face of the second extension electrode.

9. The LED package of claim 7, wherein the top faces, the bottom faces, and the lateral faces of the first and second extension electrodes are totally exposed out of the molded body.

10. The LED package of claim 1, wherein the receiving cavity extends downwardly from the top face of the reflecting cup to the top faces of the first and second electrodes.

11. The LED package of claim 10, further comprising an encapsulant layer, wherein the encapsulant layer is received in the receiving cavity to encapsulate the LED die therein.

12. The LED package of claim 1, wherein the first and second electrodes each have a T-shaped transverse cross-section along a thickness direction thereof.

13. The LED package of claim 12, wherein the first electrode comprises a first central portion and a first side portion protruding sideward from the first central portion, and the second electrode comprises a second central portion and a second side portion protruding sideward from the second central portion, and the first side portion faces toward the second side portion.

14. The LED package of claim 13, wherein the first central portion has a thickness larger than that of the first side portion, and the second central portion has a thickness larger than that of the second side portion.

15. The LED package of claim 14, wherein the first and second electrodes cooperatively define an elongate groove therebetween, and the groove comprises an upper portion and a lower portion communicating with the upper portion.

16. The LED package of claim 14, wherein the upper portion is located between the first side portion and the second side portion, and the lower portion is located between the first central portion and the second central portion.

17. The LED package of claim 1, further comprising a first slot located between the first extension electrode and the first electrode, and a second slot located between the second extension electrode and the second electrode.

18. A method of manufacturing a light emitting diode (LED) package comprising:
providing a lead frame, the lead frame comprising a plurality of pairs of electrodes arranged in a matrix, each pair of electrodes comprising a first electrode and a second electrode adjacent to the first electrode, the first electrode comprising a first top face and a first bottom face far away from the first top face, and the second electrode comprising a second top face and a second bottom face far away from the second top face, wherein a first extension electrode protrudes sideward from the first electrode away from the second electrode, and a second extension electrode protrudes sideward from the second electrode away from the first electrode, the first electrodes being arranged in a plurality of columns and the second electrodes being arranged in a plurality of columns;
forming a plurality of molded bodies to correspond to the pairs of the electrodes, each molded body surrounding and covering a plurality of pairs of the first and second electrodes disposed in two adjacent columns, and each molded body forming a plurality of reflecting cups, each reflecting cup defining a receiving cavity therein and located over a corresponding pair of the first and second electrodes, wherein the first and second extension electrodes are exposed from an outer periphery of each molded body, and the first and second bottom faces of the first and second electrodes are exposed out from a bottom face of each molded body;
disposing a plurality of LED dies in the corresponding receiving cavities, each LED die being electrically connected to the corresponding pair of first and second electrodes exposed at a bottom of the corresponding receiving cavity;
forming an encapsulant layer in the receiving cavity of each reflecting cup to encapsulate the LED die therein; and
cutting the molded bodies and the lead frame along severing lines located between two adjacent first electrodes and two adjacent second electrodes to obtain a plurality of individual LED packages, each LED package comprising a pair of first and second electrodes and an LED die.

19. The method of claim 18, wherein the adjacent first electrodes arranged in a same column are linearly connected by a first connecting bar, and the adjacent second electrodes arranged in a same column are linearly connected by a second connecting bar.

20. The method of claim 18, wherein each reflecting cup has a width larger than that of the first and second extension electrodes in a width direction of an LED package.
